(19) United States
(12) Patent Application Publication
(10) Pub. No.: US 2016/0054364 A1
(43) Pub. Date: Feb. 25, 2016

(54) POWER MONITORING SYSTEM FOR A POWER SYSTEM, AND POWER MONITORING DEVICE THEREOF

(71) Applicant: I SHOU UNIVERSITY, Kaohsiung City (TW)

(72) Inventors: Chao-Shun Chen, Kaohsiung City (TW); Te-Tien Ku, Kaohsiung City (TW); Chia-Hung Lin, Kaohsiung City (TW); Cheng-Ting Hsu, Kaohsiung City (TW)

(21) Appl. No.: 14/467,472

(22) Filed: Aug. 25, 2014

(51) Int. Cl. G01R 21/00; G01R 1/36; G01R 31/02; G01K 13/00

(52) U.S. Cl. CPC G01R 21/00; G01K 13/00; G01R 1/36; G01R 31/027

(57) ABSTRACT

A power monitoring system includes a power monitoring device and a host. The power monitoring device includes: a plurality of meters, each generating an input detection signal that indicates an electric quantity inputted to a respective load; a detecting unit generating an output detection signal that indicates an electric quantity outputted to a transformer; a processing unit generating, based on the output detection signal and the input detection signals, a state indicator that indicates the presence or absence of energy theft; and a communication unit generating a communication signal that carries the state indicator. The host generates a warning output when the state indicator carried by the communication signal received thereby indicates the presence of energy theft.

### FIELD OF THE INVENTION

This invention relates to a monitoring device, and more particularly to a power monitoring system for a power system, and a power monitoring device thereof.

### BACKGROUND OF THE INVENTION

A power system includes a transformer, and a plurality of loads coupled to the transformer for receiving energy therefrom. Conventionally, the power system is monitored manually. Therefore, without visiting the location of the transformer and the loads, one is unable to know whether there is a problem (e.g., energy theft, over-load of the transformer or over-temperature of the transformer) with the power system or not.

### SUMMARY OF THE INVENTION

Therefore, an object of the present invention is to provide a power monitoring system and a power monitoring device that can overcome the aforesaid drawback associated with the prior art.

According to one aspect of the present invention, a power monitoring system is adapted to be coupled among a transformer and a plurality of loads, and comprises a power monitoring device and a host.

The power monitoring device includes a plurality of meters, a detecting unit, a processing unit and a communication unit.

Each meter is adapted to be coupled between the transformer and a respective one of the loads so that energy is transferred from the transformer to the respective one of the loads therethrough. Each meter detects an input power of the respective one of the loads, and generates, based on the detected input power and a predetermined time period, an input detection signal that indicates an electric quantity inputted to the respective one of the loads.

The detecting unit is adapted to be coupled to the transformer, and generates an output detection signal that indicates an electric quantity outputted to the transformer.

The processing unit is coupled to the detecting unit and the meters for receiving the output detection signal and the input detection signals respectively therefrom. The processing unit generates, based on the electric quantity indicated by the output detection signal and the electric quantity indicated by each of the input detection signals, a state indicator that indicates the presence or absence of energy theft.

The communication unit is coupled to the processing unit for receiving the state indicator therefrom, and generates a communication signal that carries the state indicator.

The host is capable of establishing an electrical connection with the communication unit of the power monitoring device for receiving the communication signal therefrom, and generates a warning output when the state indicator carried by the communication signal indicates the presence of energy theft.

According to another aspect of the present invention, a power monitoring device is adapted to be coupled among a transformer and a plurality of loads, and comprises a plurality of meters, a detecting unit, a processing unit and a communication unit.

Each meter is adapted to be coupled between the transformer and a respective one of the loads so that energy is transferred from the transformer to the respective one of the loads therethrough. Each meter detects an input power of the respective one of the loads, and generates, based on the detected input power and a predetermined time period, an input detection signal that indicates an electric quantity inputted to the respective one of the loads.

The detecting unit is adapted to be coupled to the transformer, and generates an output detection signal that indicates an electric quantity outputted to the transformer.

The processing unit is coupled to the detecting unit and the meters for receiving the output detection signal and the input detection signals respectively therefrom. The processing unit generates, based on the electric quantity indicated by the output detection signal and the electric quantity indicated by each of the input detection signals, a state indicator that indicates the presence or absence of energy theft.

The communication unit is coupled to the processing unit for receiving the state indicator therefrom, and generates a communication signal that carries the state indicator.

According to yet another aspect of the present invention, a power monitoring system is adapted to be coupled to a transformer, and comprises a power monitoring device and a host. The power monitoring device includes a temperature sensor, a processing unit and a communication unit.

The temperature sensor is adapted for detecting a temperature of the transformer to generate a temperature detection signal that indicates the detected temperature.

The processing unit is coupled to the temperature sensor for receiving the temperature detection signal therefrom. The processing unit generates, based on the detected temperature indicated by the temperature detection signal, an over-temperature indicator that indicates whether there is over-temperature of the transformer or not.

The communication unit is coupled to the processing unit for receiving the over-temperature indicator therefrom, and generates a communication signal that carries the over-temperature indicator.

The host receives the communication signal from the communication unit of the power monitoring device, and generates a warning output when the over-temperature indicator carried by the communication signal indicates that the over-temperature occurs.

### BRIEF DESCRIPTION OF THE DRAWINGS

Other features and advantages of the present invention will become apparent in the following detailed description of the embodiment of this invention, with reference to the accompanying drawings, in which:

FIG. 1 is a schematic block diagram illustrating an embodiment of a power monitoring system according to this invention; and

FIG. 2 is a schematic block diagram illustrating a interface of the embodiment.

### DETAILED DESCRIPTION OF THE EMBODIMENT

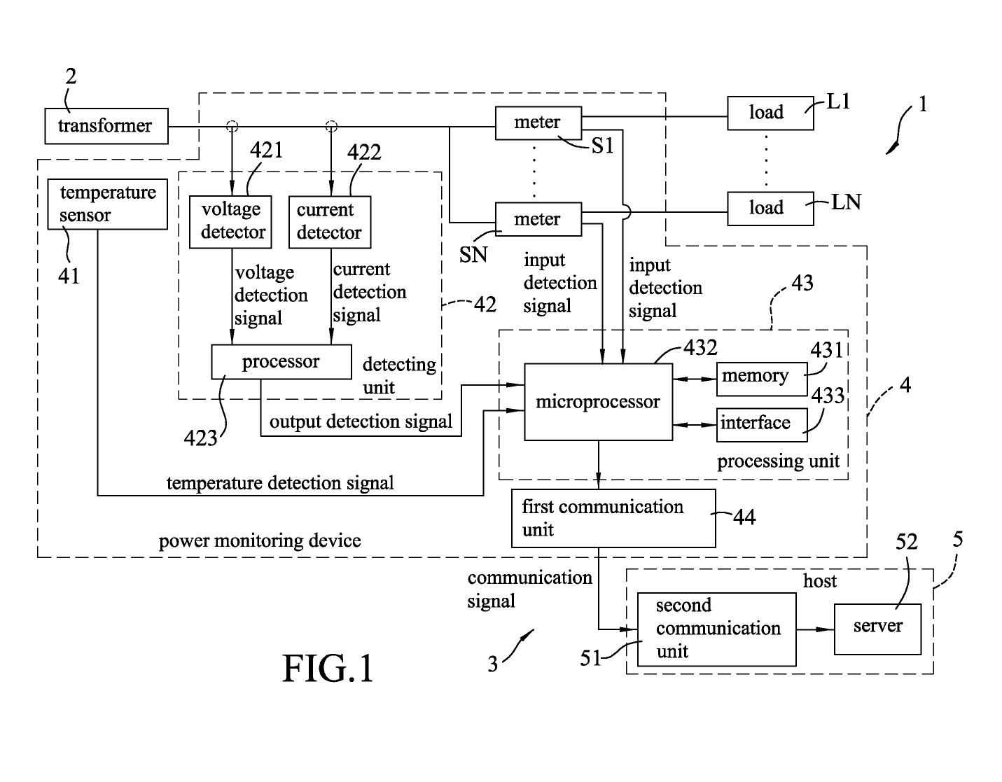

Referring to FIG. 1, the embodiment of a power monitoring system 3 according to this invention is adapted to be used in a power system 1 that includes a transformer 2 and a plurality of loads (L1˜LN). The power monitoring system 3 is adapted to be coupled among the transformer 2 and the loads (L1˜LN), and includes a power monitoring device 4 and a host 5.

The power monitoring device 4 includes a plurality of meters (S1∫SN), a temperature sensor 41, a detecting unit 42, a processing unit 43 and a first communication unit 44.

Each meter (S1˜SN), e.g., a smart meter, is adapted to be coupled between the transformer 2 and a respective one of the loads (L1˜LN) for the respective load (L1˜LN) to receive energy from the transformer 2 therethrough. Each meter (S1˜SN) detects an input power of the respective load (L1˜LN), and generates, based on the detected input power and a predetermined time period, an input detection signal that indicates an electric quantity inputted to the respective load (L1˜LN) (hereinafter referred to as “input electric quantity” of the load (L1˜LN)).

The temperature sensor 41 detects a temperature of the transformer 2 to generate a temperature detection signal that indicates the detected temperature.

The detecting unit 42 is adapted to be coupled to the transformer 2 and generates an output detection signal that indicates an electric quantity outputted by the transformer 2 (hereinafter referred to as “output electric quantity” of the transformer 2). In this embodiment, the detecting unit 42 includes a voltage detector 421, a current detector 422 and a processor 423.

The voltage detector 421 is adapted to be coupled to the transformer 2, and detects an output voltage of the transformer 2 to generate a voltage detection signal that indicates the detected output voltage.

The current detector 422 is adapted to be coupled to the transformer 2, and detects an output current of the transformer 2 to generate a current detection signal that indicates the detected output current.

The processor 423 is coupled to the voltage detector 421 and the current detector 422 for receiving the voltage detection signal and the current detection signal respectively therefrom. The processor 423 obtains an output power based on the detected output voltage indicated by the voltage detection signal and the detected output current indicated by the current detection signal, and generates the output detection signal based on the output power and the predetermined time period.

The processing unit 43 is coupled to the temperature sensor 41, the processor 423 of the detecting unit 42 and the meters (S1˜SN) for receiving the temperature detection signal, the output detection signal and the input detection signals respectively therefrom. The processing unit 43 generates, based on the output electric quantity indicated by the output detection signal and the input electric quantity indicated by each of the input detection signals, a state indicator that indicates the presence or absence of energy theft or not. The processing unit 43 generates, based on the detected temperature indicated by the temperature detection signal, an over-temperature indicator that indicates whether over-temperature occurs in the transformer 2 or not. The processing unit 43 generates, based on the output electric quantity indicated by the output detection signal, an over-load indicator that indicates whether the transformer 2 is over-loaded or not.

In this embodiment, the processing unit 43 includes a memory 431, a microprocessor 432 and an interface 433.

The memory 431 stores a reference temperature value and a reference electric quantity.

The microprocessor 432 is coupled to the meters (S1˜SN), the processor 423 of the detecting unit 42, the temperature sensor 41 and the memory 431 for receiving the input detection signals respectively from the meters (S1˜SN), the output detection signal from the processor 423, the temperature detection signal from the temperature sensor 41, and the reference temperature value and the reference electric quantity from the memory 431.

The microprocessor 432 adds the input electric quantities indicated respectively by the input detection signals to obtain a total input electric quantity. The microprocessor 432 compares the total input electric quantity with the output electric quantity indicated by the output detection signal to obtain the state indicator.

The microprocessor 432 compares the detected temperature indicated by the temperature detection signal with the reference temperature value to obtain the over-temperature indicator.

The microprocessor 432 compares the output electric quantity indicated by the output detection signal with the reference electric quantity to obtain the over-load indicator.

The microprocessor 432 may further receive the current detection signal from the processor 423 of the detecting unit 42, and may calculate, based on the detected current indicated by the current detection signal, copper loss of the transformer 2 which is proportional to the square of the output current of the transformer 2.

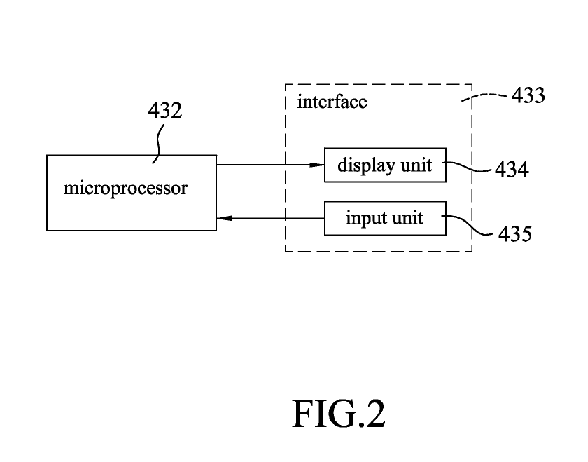

Referring to FIG. 2, the interface 433 includes a display unit 434 and an input unit 435. The display unit 434 is coupled to the microprocessor 432 for displaying the state indicator, the over-temperature indicator and the over-load indicator therefrom. The input unit 435 is coupled to the microprocessor 432. When operated by a user, the input unit 435 generates a control signal for setting operating parameters of the microprocessor 432.

Referring to FIG. 1, the first communication unit 44 is coupled to the microprocessor 432 of the processing unit 43 for receiving the state indicator, the over-temperature indicator and the over-load indicator therefrom, and generates a communication signal that carries these indicators.

The host 5 includes a second communication unit 51 and a server 52.

The second communication unit 51 is capable of establishing an electrical connection with the first communication unit 44 so as to receive the communication signal therefrom, and obtains the state indicator, the over-temperature indicator and the over-load indicator from the communication signal. The first and second communication units 44, 51 may communicate with each other through a ZigBee network or using power line communication (PLC) techniques.

The server 52 is coupled to the second communication unit 51 for receiving the state indicator, the over-temperature indicator and the over-load indicator therefrom. The server 52 performs the following: generating a first warning output when the state indicator indicates that the presence of energy theft; generating a second warning output when the over-temperature indicator indicates that over-temperature has occurred in the transformer 2; and generating a third warning output when the over-load indicator indicates that the transformer 2 is overloaded.

Herein, while the power monitoring device 4 may be disposed alongside the transformer 2, the host 5 may be situated at a remote location from the power monitoring device 4. With the implementation of the first communication unit 44 in the power monitoring device 4 and the second communication unit 51 in the host 5 that are communicating with each other, real-time remote monitoring of the transformer 2 is achievable, such that the power monitoring system 3 of this invention is able to generate a warning to inform relevant personnel of possible occurrences of problems, such as energy theft, over-temperature or over-load of the transformer 2, in order to have the problems resolved in a timely fashion.

While the present invention has been described in connection with what is considered the most practical embodiment, it is understood that this invention is not limited to the disclosed embodiment but is intended to cover various arrangements included within the spirit and scope of the broadest interpretation and equivalent arrangements.

What is claimed is:

1. A power monitoring system adapted to be coupled among a transformer and a plurality of loads, said power monitoring system comprising:
a power monitoring device including
a plurality of meters, each of which is adapted to be coupled between the transformer and a respective one of the loads so that energy is transferred from the transformer to the respective one of the loads therethrough, each of said meters detecting an input power of the respective one of the loads, and generating, based on the detected input power and a predetermined time period, an input detection signal that indicates an electric quantity inputted to the respective one of the loads,
a detecting unit adapted to be coupled to the transformer, and generating an output detection signal that indicates an electric quantity outputted by the transformer,
a processing unit coupled to said detecting unit and said meters for receiving the output detection signal and the input detection signals respectively therefrom, said processing unit generating, based on the electric quantity indicated by the output detection signal and the electric quantity indicated by each of the input detection signals, a state indicator that indicates the presence or absence of energy theft, and
a first communication unit coupled to said processing unit for receiving the state indicator therefrom, and generating a communication signal that carries the state indicator; and
a host capable of establishing an electrical connection with said first communication unit of said power monitoring device for receiving the communication signal therefrom, and generating a first warning output when the state indicator carried by the communication signal indicates the presence of energy theft.

2. The power monitoring system of claim 1, wherein said detecting unit includes:
a voltage detector adapted to be coupled to the transformer for detecting an output voltage of the transformer to generate a voltage detection signal that indicates the detected output voltage;
a current detector adapted to be coupled to the transformer for detecting an output current of the transformer to generate a current detection signal that indicates the detected output current; and
a processor coupled to said voltage detector and said current detector for receiving the voltage detection signal and the current detection signal respectively therefrom, said processor obtaining an output power based on the detected output voltage indicated by the voltage detection signal and the detected output current indicated by the current detection signal, and generating the output detection signal based on the output power and the predetermined time period.

3. The power monitoring system of claim 1, wherein said processing unit includes:
a microprocessor coupled to said meters and said detecting unit for receiving the input detection signals and the output detection signal respectively therefrom;
said microprocessor adding the electric quantities indicated respectively by the input detection signals to obtain a total input electric quantity;
said microprocessor comparing the total input electric quantity with the electric quantity indicated by the output detection signal to obtain the state indicator.

4. The power monitoring system of claim 3, wherein said power monitoring device further includes:
a temperature sensor adapted for detecting a temperature of the transformer to generate a temperature detection signal that indicates the detected temperature.

5. The power monitoring system of claim 4, wherein said processing unit further includes a memory storing a reference temperature value;
said microprocessor of said processing unit being further coupled to said temperature sensor and said memory for receiving the temperature detection signal and the reference temperature value respectively therefrom;
said microprocessor comparing the detected temperature indicated by the temperature detection signal with the reference temperature value to obtain an over-temperature indicator that indicates whether over-temperature occurs in the transformer or not.

6. The power monitoring system of claim 5, wherein said memory further stores a reference electric quantity;
said microprocessor further receiving the reference electric quantity from said memory;
said microprocessor comparing the electric quantity indicated by the output detection signal with the reference electric quantity to obtain an over-load indicator that indicates whether the transformer is over-loaded or not.

7. The power monitoring system of claim 6, wherein said first communication unit of said power monitoring device is coupled to said microprocessor of said processing unit for receiving the state indicator, the over-temperature indicator and the over-load indicator therefrom, the communication signal generated by said first communication unit further carrying the over-temperature indicator and the over-load indicator,
said host including:
a second communication unit capable of establishing an electrical connection with said first communication unit for receiving the communication signal therefrom, and obtaining the state indicator, the over-temperature indicator and the over-load indicator from the communication signal; and
a server coupled to said second communication unit for receiving the state indicator, the over-temperature indicator and the over-load indicator therefrom, said server generating the first warning output when the state indicator indicates the presence of energy theft, further generating a second warning output when the over-temperature indicator indicates that over-temperature occurs, and further generating a third warning output when the over-load indicator indicates that the transformer is over-loaded.

8. A power monitoring device adapted to be coupled among a transformer and a plurality of loads, said power monitoring device comprising:
a plurality of meters, each of which is adapted to be coupled between the transformer and a respective one of the loads so that energy is transferred from the transformer to the respective one of the loads therethrough, each of said meters detecting an input power of the respective one of the loads, and generating, based on the detected input power and a predetermined time period, an input detection signal that indicates an electric quantity inputted to the respective one of the loads;
a detecting unit adapted to be coupled to the transformer, and generating an output detection signal that indicates an electric quantity outputted by the transformer;
a processing unit coupled to said detecting unit and said meters for receiving the output detection signal and the input detection signals respectively therefrom, said processing unit generating, based on the electric quantity indicated by the output detection signal and the electric quantity indicated by each of the input detection signals, a state indicator that indicates the presence or absence of energy theft; and
a communication unit coupled to said processing unit for receiving the state indicator therefrom, and generating a communication signal that carries the state indicator.

9. The power monitoring device of claim 8, wherein said detecting unit includes:
a voltage detector adapted to be coupled to the transformer for detecting an output voltage of the transformer to generate a voltage detection signal that indicates the detected output voltage;
a current detector adapted to be coupled to the transformer for detecting an output current of the transformer to generate a current detection signal that indicates the detected output current; and
a processor coupled to said voltage detector and said current detector for receiving the voltage detection signal and the current detection signal respectively therefrom, said processor obtaining an output power based on the detected output voltage indicated by the voltage detection signal and the detected output current indicated by the current detection signal, and generating the output detection signal based on the output power and the predetermined time period.

10. The power monitoring device of claim 8, wherein said processing unit includes:
a microprocessor coupled to said meters and said detecting unit for receiving the input detection signals and the output detection signal respectively therefrom;
said microprocessor adding the electric quantities indicated respectively by the input detection signals to obtain a total input electric quantity;
said microprocessor comparing the total input electric quantity with the electric quantity indicated by the output detection signal to obtain the state indicator.

11. The power monitoring device of claim 10, further comprising:
a temperature sensor adapted for detecting a temperature of the transformer to generate a temperature detection signal that indicates the detected temperature.

12. The power monitoring device of claim 11, wherein said processing unit further includes a memory storing a reference temperature value;
said microprocessor of said processing unit being further coupled to said temperature sensor and said memory for receiving the temperature detection signal and the reference temperature value respectively therefrom;
said microprocessor comparing the detected temperature indicated by the temperature detection signal with the reference temperature value to obtain an over-temperature indicator that indicates whether over-temperature occurs in the transformer or not.

13. The power monitoring device of claim 12, wherein said memory further stores a reference electric quantity;
said microprocessor further receiving the reference electric quantity from said memory;
said microprocessor comparing the electric quantity indicated by the output detection signal with the reference electric quantity to obtain an over-load indicator that indicates whether the transformer is over-loaded or not.

14. A power monitoring system adapted to be coupled to a transformer, said power monitoring system comprising:
a power monitoring device including
a temperature sensor adapted for detecting a temperature of the transformer to generate a temperature detection signal that indicates the detected temperature,
a processing unit coupled to said temperature sensor for receiving the temperature detection signal therefrom, said processing unit generating, based on the detected temperature indicated by the temperature detection signal, an over-temperature indicator that indicates whether there is over-temperature of the transformer or not, and
a first communication unit coupled to said processing unit for receiving the over-temperature indicator therefrom, said communication unit generating a communication signal that carries the over-temperature indicator; and
a host capable of establishing an electrical connection with said first communication unit of said power monitoring device for receiving the communication signal therefrom, and generating a warning output when the over-temperature indicator carried by the communication signal indicates that over-temperature occurs.

15. The power monitoring system of claim 14, wherein said processing unit of said power monitoring device includes:
a memory storing a reference temperature value; and
a microprocessor coupled to said temperature sensor and said memory for receiving the temperature detection signal and the reference temperature value therefrom;
said microprocessor comparing the detected temperature indicated by the temperature detection signal with the reference temperature value to obtain the over-temperature indicator.

16. The power monitoring system of claim 15, wherein said power monitoring device further includes:
a detecting unit adapted to be coupled to the transformer, and generating, an output detection signal that indicates an electric quantity outputted by the transformer.

17. The power monitoring system of claim 16, wherein said detecting unit includes:
a voltage detector adapted to be coupled to the transformer, and detecting an output voltage of the transformer to generate a voltage detection signal that indicates the detected output voltage;
a current detector adapted to be coupled to the transformer, and detecting an output current of the transformer to generate a current detection signal that indicates the detected output current; and
a processor coupled to said voltage detector and said current detector for receiving the voltage detection signal and the current detection signal respectively therefrom, said processor obtaining an output power based on the detected output voltage indicated by the voltage detection signal and the detected output current indicated by the current detection signal, and generating the output detection signal based on the output power and a predetermined time period.

18. The power monitoring system of claim 16, wherein said memory of said processing unit further stores a reference electric quantity;
said microprocessor of said processing unit being further coupled to said detecting unit for receiving the output detection signal therefrom, and further receiving the reference electric quantity from said memory;
said microprocessor comparing the electric quantity indicated by the output detection signal with the reference electric quantity to obtain an over-load indicator that indicates whether there is the transformer is over-loaded or not.

19. The power monitoring system of claim 18, wherein said first communication unit is coupled to said microprocessor for receiving the over-temperature indicator and the over-load indicator therefrom, the communication signal further carrying the over-load indicator.

20. The power monitoring system of claim 19, wherein said host includes:
a second communication unit capable of establishing an electrical connection with said first communication unit of said power monitoring device for receiving the communication signal therefrom, and obtaining the over-temperature indicator and the over-load indicator from the communication signal; and
a server coupled to said second communication unit for receiving the over-temperature indicator and the over-load indicator therefrom, said server generating the warning output when the over-temperature indicator indicates that over-temperature occurs, and generating another warning output when the over-load indicator indicates that the transformer is over-loaded.
